(19) United States
(12) Patent Application Publication
(10) Pub. No.: US 2007/0279079 A1
(43) Pub. Date: Dec. 6, 2007

(54) Multiple chip package test program and programming architecture

(76) Inventor: Jianxiang Chang, Milpitas, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/443,733

(22) Filed: May 31, 2006

(51) Int. Cl. G01R 31/26

(52) U.S. Cl. 324/765

(57) ABSTRACT

A two-layer multi-chip package (MCP) test program architecture, test program, and programming method for testing an MCP. A program implemented according to the architecture includes a global layer defining global resources and global test functions, and respective local layers associated with each of a plurality of dies in the MCP defining respective local resources and respective local test functions specific to the respective dies.

### BACKGROUND OF THE INVENTION

The present invention relates generally to integrated circuit testing, and more particularly to a novel program architecture for testing a multi-chip package (MCP).

As semiconductor technology becomes more complicated and compact, a new type of semiconductor device has emerged. This device, called a multiple chip package (MCP), normally contains several smaller semiconductor devices (or dies) in one larger package. Each die in the package has been separately tested before being integrated into the MCP. When each die is integrated into the MCP, the pin assignment test flow can be changed according to how the MCP is designed. While MCP test programs exist, these programs cut and paste each test program's source code into one MCP program, causing version control problems and high cost of correlation for testing different MCP devices.

The challenge is to develop an MCP device test program based on the existing separate die test programs.

### SUMMARY OF THE INVENTION

Embodiments of the invention include a method for creating a test program for a multi-chip package (MCP), comprising defining global resources associated with the MCP, the global resources comprising a global pin list of the MCP, zero or more global variables, and zero of more global test function; defining local resources associated with each of the dies in the MCP; implementing respective local test functions specific to each of the respective dies of the MCP; and implementing a global test program that calls the respective test functions.

Embodiments of the invention also include a method of executing a test program for a multi-chip package (MCP), comprising defining global resources associated with the MCP, the global resources comprising a global pin list of the MCP, zero or more global variables, and zero of more global test function; defining local resources associated with each of the dies in the MCP; and executing a global test program that calls each of a plurality of respective local test functions, each of the respective local test functions specific to a corresponding respective die of the MCP.

Embodiments of the invention include a multi-chip package (MCP) device test program comprising a respective different local layer associated with each die of the MCP, each respective different local layer comprising respective local definitions and respective local code relating to the respective die; and a global layer comprising definitions and code relating to global resources; wherein the global resources comprise global pin list definitions, and global test functions, and wherein the global layer comprises code that invokes each of the different local layers to test each of the die associated with the respective different local layers.

Embodiments of the invention include a computer readable storage medium tangibly embodying program instructions implementing a method for executing a test program for a multi-chip package (MCP), the method comprising the steps of defining global resources associated with the MCP, the global resources comprising a global pin list of the MCP, zero or more global variables, and zero of more global test function; defining local resources associated with each of the dies in the MCP; and executing a global test program that calls each of a plurality of respective local test functions, each of the respective local test functions specific to a corresponding respective die of the MCP.

### BRIEF DESCRIPTION OF THE DRAWINGS

A more complete appreciation of this invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a cross-sectional side view of a multi-chip package (MCP);

FIG. 2 is a diagram illustrating a test environment for a multi-insertion test;

FIG. 3 is a diagram illustrating a single insertion test environment;

FIG. 4 illustrates a common MCP cut and paste programming technique and resulting correlation problem;

FIG. 5 is a block diagram illustrating a two-part MCP test program architecture;

FIG. 6 is a more detailed block diagram illustrating an embodiment of an MCP device test program architecture;

FIG. 7 is a functional diagram illustrating the function of a pin list development tool;

FIG. 8 is an example MCP device test program architecture; and

FIG. 9 is an example code sample illustrating the architecture of an MCP device program architecture.

### DETAILED DESCRIPTION

This present invention is a new test program architecture that separates MCP test resources into two layers—a local test resource and a global test resource. This MCP test program can integrate any test program by accessing both the local test resource and global test resource. The MCP test program also contains a mechanism that allows a program developer to automatically scan through the test program of the individual dies to find the global test resource such as a test function or APG entry point in each die's test program. The test program then integrates this information into the final MCP test program seamlessly.

This novel test program architecture allows the MCP test program developer to develop MCP programs with minimal change to each individual die test program, provides an automatic global resource conversion tool, and thereby avoids version control problems and high correlation costs.

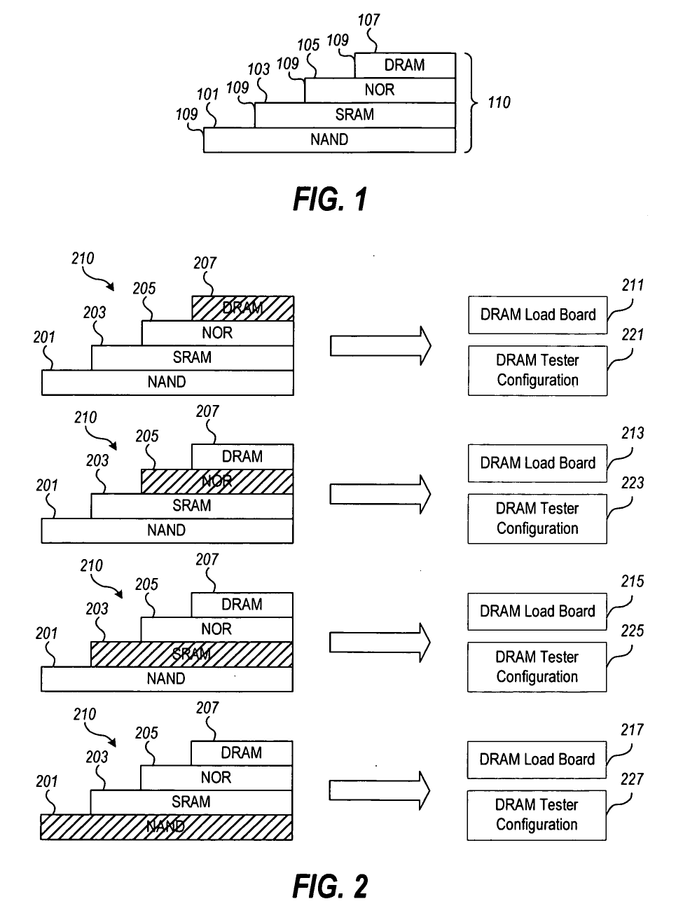

Turning now to the drawings, FIG. 1 illustrates a Multi-Chip Package (MCP) 110 which contains more than one integrated circuit die. These individual dies 109 are stacked one on top of another. Within these die stacks, any mix of die types can be combined. For example, the illustrative embodiment includes a die stack including NAND 101, NOR 105, SRAM 103, or DRAM 107 dies 109. Each die 109 is tested before being stacked and each die has its own set of pins for testing 112. Once in the stack, testing is done sequentially, one memory after another.

To test an MCP, manufacturers have previously had to use multiple tester configurations, one for each type of die as illustrated by FIG. 2. Each test configuration would require a different load board, so each MCP would require multiple load boards for the various tests. The example in FIG. 2 shows an MCP 210 with different respective load boards 211, 213, 215, 217 and different respective tester configurations 221, 223, 225, 227 for DRAM 201, NOR 203, SRAM 205, and NAND 207. As is to be understood, any combination of different dies, and therefore different types of load boards and associated tester configurations, is possible. This type of testing is known as multi-insertion testing, and the problems associated with multi-insertion testing include higher costs because of the multiple load boards and yield loss with each insertion.

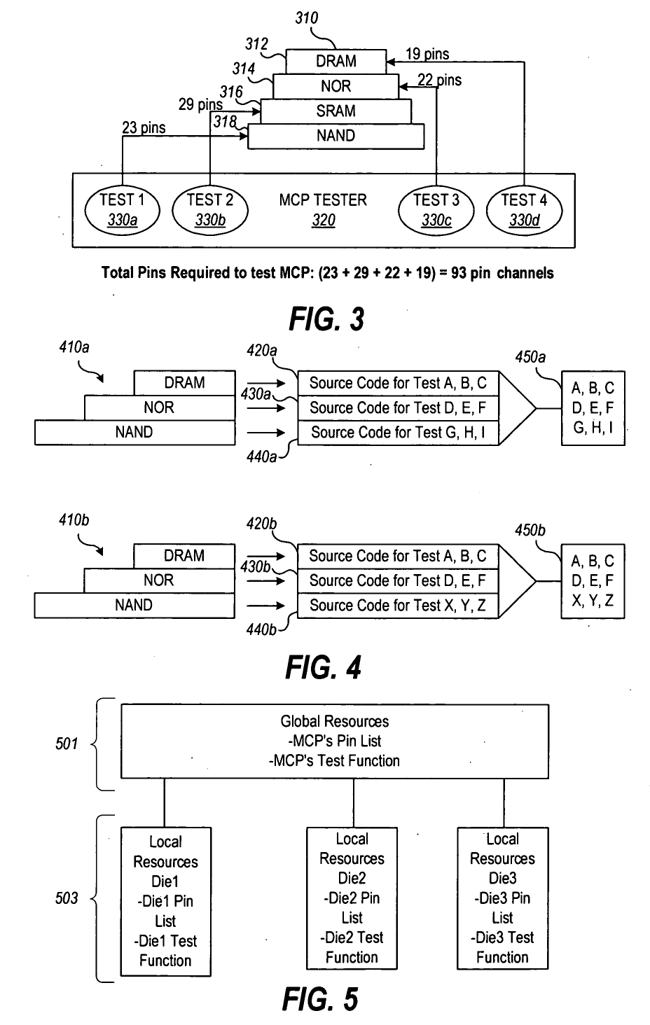

FIG. 3 illustrates a single insertion test of an MCP 310. Single insertion testing is a faster alternative to multi-insertion testing. Single-insertion testing requires a tester capable of connecting to each pin of each die 312, 314, 316, 318 necessary for conducting the testing of each die. Single-insertion testing requires less time to test because the MCP testing does not require loading of the MCP onto different load boards or different tester setup configuration for each die in the stack. It also avoids yield loss by making a single insertion for the entire MCP. However, single-insertion testing also has limitations. Single-insertion testing requires high I/O pin count testers because it must include an I/O pin for each pin of each MCP device. Further, the tester must have the capability to fully test all the memory dies stacked in the MCP by accommodating the different pin counts, power, speed, and accuracy of each die. Where the tester lacks the performance to test all the dies in the MCP, additional insertions are necessary.

An additional limitation on single-insertion testing is that single-insertion testers test MCPs one memory die at a time 301. In each individual die test, only a small number of the total pins required to test the MCP are used. For example, if DRAM die 312 requires 19 pins to test, and NOR die 314 requires 22 pins to test, and SRAM die 316 requires 29 pins to test, and NAND die 318 requires 23 pins to test, then the total number of pins required to execute the single-insertion test is 93 pins (and therefore 93 pin electronics channels). During any one of the tests 330a, 330b, 330c, 330d, only a relatively small subset of the pins are utilized. The result is low tester resource utilization as most of the hardware required to meet the MCP's pin count sits idle during the test.

This present invention is a new test program architecture that is designed to develop MCP test programs based on existing test programs for the individual memory dies.

FIG. 4 illustrates a common MCP cut and paste program and a resulting correlation problem. Contained within an MCP 410a, 410b are multiple dies 412a, 414a, 416a, and 412b, 414b, 416b. Each individual die 412a, 414a, 416a, and 412b, 414b, 416b has its own test program 420a, 430a, 440a, and 420b, 430b, 440b. To test an MCP what is needed is a test program that contains every individual die test program. Previously, each individual die's test program's source code 420a, 430a, 440a, and 420b, 430b, 440b was cut and pasted into a single MCP test program 450a, 450b. The resulting MCP test program is suited only for the MCP being tested and cannot be used for testing MCP devices with differing types of dies. This is illustrated in FIG. 4 by comparing MCP Device 410a to MCP Device 410b. The test program 450a for MCP Device 410a is not identical to the test program 450b for MCP Device 410b. To test another MCP device therefore requires more programming, resulting in higher costs.

Embodiments of the invention divide the test resource into two parts as illustrated in FIG. 5: a global resource 501 and a local resource 503. A global resource 501 is a resource that applies to the whole MCP package. Examples of global resources are things like the MCP's pinlist, and the MCP's test function. A local resource 503 is a resource that applies to an individual die. Examples of local resources are things like the die's pinlist, and the die's test function.

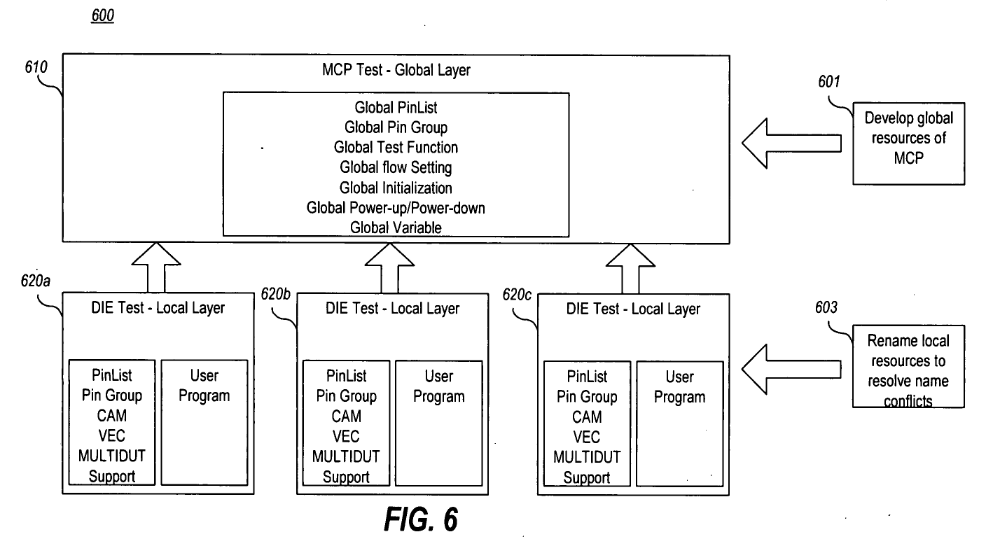

FIG. 6 is illustrates an embodiment of an MCP device test program architecture 600 and associated method to create an MCP device test program. As illustrated, the test program architecture 600 includes a global layer 610 and a local layer 620. The global layer 610 includes definitions and code relating to global resources, for example, Global Pin List definitions, Pin Grouping definitions, global variable definitions, global test function definitions and associated code, power up and power down sequencing code, etc.). The global layer 610 may include functionality for interfacing with the tester to reconfigure the PE channels to connect to the pins defined in the local pin list of a selected die prior to executing the test specific to that die.

The local layer 620 includes local definitions and local code relating to the particular die under test. A different local layer 620a, 620b, 620c is defined for each die to be tested. The local layer interfaces with the global layer using a common Application Program Interface (API).

To create an MCP test program using this two-part architecture 600, the programmer first develops the global resources of the MCP (step 601). To develop the global resource 601, the programmer must define elements such as the global pin list, the global test function, the global flow setting etc. After defining the global resources of the MCP, the programmer then renames local resources (step 603) such as the pinlist or test function to resolve name conflicts between global and local resources.

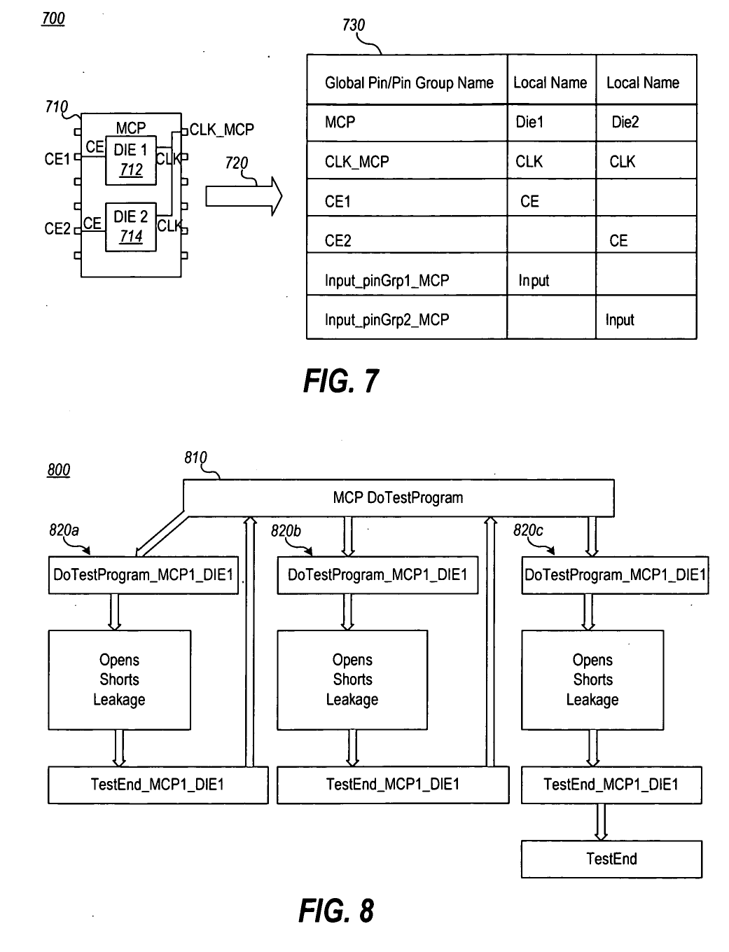

To facilitate creating an MCP test program, the test software may contain a pin list development tool support which assists in mapping between the MCP (global) pins and the die (local) pins. FIG. 7 illustrates the function of an embodiment of a such a pin list development tool. Given a definition of the MCP's pin list, the pin list development tool then provides a mapping between the MCP (global pin) and the die (local) pin. This is seen in the example of FIG. 7, where, given the Pin List 720 of an MCP 710 having two die 712, 714, each with certain identical pin names (CE and CLK), the pin list development tool generates a map 730 which maps global pin names to local pin names, renaming local pin names where necessary to resolve conflict. For example, in the mapping of FIG. 7, the tool maps global pin name CE1 to local pin CE of Die 1, and global pin name CE2 to local pin CE of Die 2.

The test software may also include additional development tool support utilities. For example, a naming utility may provide automatic remapping of local resource or function or variable names to global resource or function of variable names. Such naming utility may automatically run during the test program compilation.

FIG. 8 illustrates an architecture of an example of a MCP Device Test Program 800. An MCP global program 810 executes each individual local die test programs 820a, 820b, 820c. For example, the global program 810 may run a test for die 1, looking for opens, shorts, or current leakage, then ending the test for die 1 and starting the test 820b for die 2. After testing die 2 for opens, shorts, or leaks, the test for die 2 ends and the test 820c for die 3 begins. After testing die 3, the global test 810 is then complete.

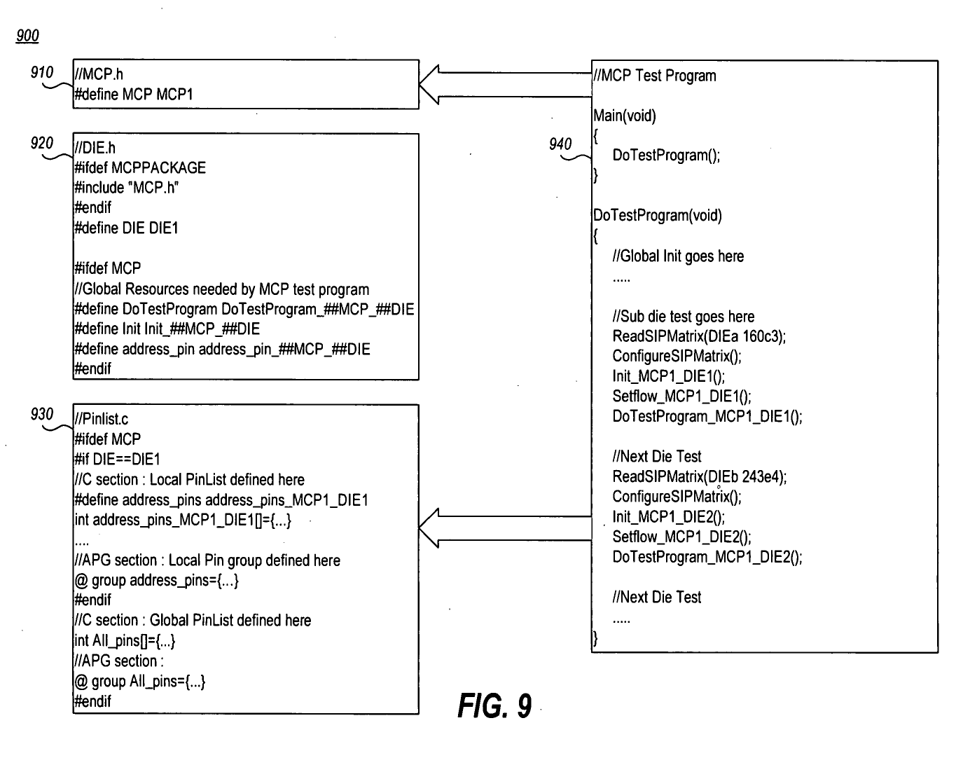

FIG. 9 is a code sample 900 written in the C programming language that illustrates the MCP test program architecture. The code includes resource definition files, including a global resource definition file MCP.h, a local resource definition file DIE.h, and a pinlist definition file Pinlist.c. The Pinlist.c file utilizes an ifdef statement to define the local pin names. The code also includes an MCP test program (Main and DoTestProgram) 940 which operates to read the test configuration of the current die under test (DIE1), configure the pin electronics channel matrix of the tester, initialize the current die under test (DIE1), set the test flow for the current die under test (DIE1), and run the test (DoTestProgram_MCP1_DIE1) associated with the current die under test.

The MCP test program then moves on to the next die, and executes a similar set of functions associated with the next die, and so on. Any number of dies may be included by defining corresponding appropriate pin definitions and local and global resources. Thus, to test two dies in an MCP package, for example, the MCP Test Program may include statements to the effect of:

ChipSelect1( ); //MCP Program selects Die 1, connecting matrix to pins of Die1

DoTestProgram_MCP_Die1( ); //MCP Program call die 1's test function

ChipSelect2( ); //MCP Program selects Die 2, connecting matrix to pins of Die2

DoTestProgram_MCP_Die2( ); //MCP Program call die 2's test function

As will be appreciated by those skilled in the art, MCP test programs that utilize the architecture of embodiments of the invention allow testing of an entire MCP device utilizing a single test, and a single load board (if any).

Finally, those of skill in the art will appreciate that the invented method and apparatus described and illustrated herein may be implemented in software, firmware or hardware, or any suitable combination thereof. Preferably, the method and apparatus are implemented in software, for purposes of low cost and flexibility. Furthermore, as is clear by people skilled in the art, all software or firmware implementing the method and apparatus of the invention is executed on a computer by a computer processor which reads and executes program instructions of the software or firmware. The instructions of the software or firmware implementing embodiments of the invention may be stored for execution on a computer-readable medium and may be executed by any suitable instruction processor. Alternative embodiments are contemplated, however, and are within the spirit and scope of the invention.

Although this preferred embodiment of the present invention has been disclosed for illustrative purposes, those skilled in the art will appreciate that various modifications, additions and substitutions are possible, without departing from the scope and spirit of the invention as disclosed in the accompanying claims.

What is claimed is:

1. A method for creating a test program for a multi-chip package (MCP), comprising:
defining global resources associated with the MCP, the global resources comprising a global pin list of the MCP, zero or more global variables, and zero of more global test function;
defining local resources associated with each of the dies in the MCP;
implementing respective local test functions specific to each of the respective dies of the MCP; and
implementing a global test program that calls the respective test functions.

2. The method of claim 1, further comprising:
renaming local resources that conflict with global resource names to resolve name conflicts between global and local resources.

3. The method of claim 1, further comprising:
prior to each call of a local test function, inserting a pin connection function which configures tester connections to connect to local pins of the die associated with the local test function to be called to tester resources.

4. The method of claim 3, wherein the tester connections to each of the dies in the MCP are independent tester resources.

5. The method of claim 1, wherein the respective test functions are independent and which execute simultaneously when called by the global test program.

6. A method of executing a test program for a multi-chip package (MCP), comprising:
defining global resources associated with the MCP, the global resources comprising a global pin list of the MCP, zero or more global variables, and zero of more global test function; and
defining local resources associated with each of the dies in the MCP;
executing a global test program that calls each of a plurality of respective local test functions, each of the respective local test functions specific to a corresponding respective die of the MCP.

7. The method of claim 6, wherein:
the respective test functions utilize independent tester resources and execute simultaneously.

8. The method of claim 6, wherein:
local resources associated with corresponding respective dies that have local resource names that conflict with global resource names are renamed to resolve name conflicts between global and local resources.

9. The method of claim 6, further comprising:
prior to calling each of the plurality of a local test functions, configuring tester connections to connect to local pins of the die associated with the local test function to be called with tester resources.

10. The method of claim 9, wherein the respective test functions utilize independent tester resources and execute simultaneously.

11. A multi-chip package (MCP) device test program comprising:
a respective different local layer associated with each die of the MCP, each respective different local layer comprising respective local definitions and respective local code relating to the respective die; and
a global layer comprising definitions and code relating to global resources; wherein the global resources comprise global pin list definitions, and global test functions, and wherein the global layer comprises code that invokes each of the different local layers to test each of the die associated with the respective different local layers.

12. The MCP of claim 11, further comprising:
a pin configuration function which interfaces with the tester to configure pin electronic channels to connect pins of the tester to the pins defined in the local pin list of a selected die prior to executing the test specific to that die.

13. The MCP of claim 11, wherein the respective pin electronic channels comprise independent tester resources.

14. The MCP of claim 11, further comprising:
a pin list development tool which receives the global pin list definitions and the respective local pin list definitions, and provides a mapping between global pin in the global pin list definitions and the respective local pins of the respective local dies.

15. A computer readable storage medium tangibly embodying program instructions implementing a method for executing a test program for a multi-chip package (MCP), the method comprising the steps of:
defining global resources associated with the MCP, the global resources comprising a global pin list of the MCP, zero or more global variables, and zero of more global test function; and
defining local resources associated with each of the dies in the MCP;
executing a global test program that calls each of a plurality of respective local test functions, each of the respective local test functions specific to a corresponding respective die of the MCP.

16. The computer readable storage medium of claim 15, wherein:
executing the respective test functions simultaneously.

17. The computer readable storage medium of claim 15, wherein the instructions comprise:
renaming local resources associated with corresponding respective dies that have local resource names that conflict with global resource names to resolve name conflicts between global and local resources.

18. The computer readable storage medium of claim 15, the instructions further comprising:
prior to calling each of the plurality of a local test functions, configuring tester connections to connect to local pins of the die associated with the local test function to be called with tester resources.

19. The computer readable storage medium of claim 15, wherein the respective test functions utilize independent tester resources and execute simultaneously.
